(19) United States
(12) Patent Application Publication
(10) Pub. No.: US 2002/0170162 A1
(43) Pub. Date: Nov. 21, 2002

(54) Method and device for testing and energization-heating a stator coil

(76) Inventor: Hitoshi Suzuki, Shuuchi-gun (JP)

Correspondence Address: ERNEST A. BEUTLER, ATTORNEY AT LAW, 500 NEWPORT CENTER DRIVE, SUITE 945, NEWPORT BEACH, CA, 92660, US

(21) Appl. No.: 09/681,678

(22) Filed: May 18, 2001

(51) Int. Cl. H02K 15/00; G01R 1/00; H01F 7/06

(52) U.S. Cl. 29/596; 29/606; 29/732; 29/593

(57) ABSTRACT

An improved method and apparatus for winding electrical coils and testing them, including heat bonding of resinous coating of the windings. Both the heat bonding and testing occur in the same apparatus and the testing takes place before the heat bonding so that if the winding is not satisfactory, it can be repaired rather than scraped.

### BACKGROUND OF INVENTION

This invention relates to a method and device for testing and heat bonding an electrical coil for a rotating electrical machine.

Many types of rotating electrical machines employ one or more coil windings. A typical machine of this type is shown in FIG. 1 wherein a magneto generator that is adapted to be associated with the crankshaft of an internal combustion engine is indicated generally by the reference numeral 11. The magneto generator 11 is, in the illustrated construction, designed so as to provide a source of electrical power for the associated engine, for example for firing its spark plugs.

The magneto generator 11 is comprised of a stator assembly, indicated generally by the reference numeral 12 which is associated with a flywheel assembly, indicated generally by the reference numeral 13 and shown in phantom. The flywheel assembly 13 is affixed for rotation with an engine crankshaft 14 and has a generally cup-shaped flywheel portion 15 upon which a plurality of permanent magnet segments 16 are affixed.

The stator assembly 12 has a core 17 which has an opening that passes the crankshaft 14 and which is fixed against rotation to the body of the associated engine in a suitable manner. This core 17 has a plurality of armature poles 18, which, like the remainder of the core 17, is formed from a plurality of laminated metal plates 19. The core plates 19 are comprised of thin plates of silicone or carbon steel laminated with insulating layers.

Contained around each pole 18 is a winding 21, which is wound around a bobbin 22. The bobbin 22 is comprised of a pair of halves which encircle the laminated poles 18 and which is made by an insulating plastic by injection molding.

The afore-described construction describes the stator of a rotating magneto generator of the AC type. However, it should be understood that the invention herein may be utilized in conjunction with the manufacture and testing of a plurality of types of electric coils, which may be either fixed against rotation or rotatable in the associated machine. Also, these coils may either form portions of a generator or portions of an electric motor.

Referring now to FIG. 2, which shows the prior art type of apparatus normally utilized for winding, heat-bonding and testing the stator 12 and specifically the coils 21 thereof and to the left-hand or conventional side view of FIG. 3 which shows the procedure in performing the winding, the disadvantages of the prior art type of method and apparatus will be described.

The core assembly 17 is first placed in a winding machine, indicated by the reference numeral 23, which is designed so as to specifically wind the wire around the core 18 to form the coil 21. This is performed at the step S1 in the Prior Art method shown in FIG. 3.

After the windings 21 have been completed, the wound core assembly 12 is removed from the winding machine 23 and is placed into an energization-heating machine 24. Then at the step S2 the terminals of the energization-heating machine are connected to the coil terminals 21 a. It should be noted that FIG. 2 only shows one pair of the coil windings, but there are three such pairs in the illustrated embodiment.

Then after the connections are completed at the step S2, there is an energization heating performed by passing a large current through the coil windings for a short time, this also occurring in the machine 24. This is done so as to fuse and solidify epoxy resin, which applied to the wire of winding of the stator core so as to stabilize the contact between the windings and the connection between the windings and the bobbin 22 onto which the windings are wound.

Then the procedure moves to the step S4 where the windings are cooled so that the apparatus can then be moved to an assembly line 25 wherein lead wires 26 are connected. This occurs at the step S5.

Then, at the step S6 the apparatus is moved to a testing machine 27 wherein a connection to the lead wires 26 is made with a device that performs a waveform test to see if the winding has been properly made. This applies a charge over a time period to determine the damping characteristics of the voltage and current by application of a rectangular wave of constant voltage for a plurality of times.

If, at the step S6 it is determine that the completed assembly is satisfactory, it is then removed from the testing machine 27 and shipped at the step S7.

Thus, in connection with conventional apparatus and method the wound coil 21 must be moved from one station to another a number of times and the testing is not done until after the stator assembly 12 has been completed. Thus, if there is an error in the winding of the coils 21, then the entire stator 12 must be scraped because it cannot be fixed.

In addition, the cooling time is lengthened because there must be a cooling step S4 to cool the device to a temperature low enough for the wave-form testing at the step 56 and the connections being made at the step S5.

It is, therefore, a principal object to this invention to provide an improved and simplified method and apparatus for assembling, heat bonding and testing of an electrical coil that minimizes the number of transfers that must be made.

It is a further object to this invention to provide a method and apparatus for performing this bonding and testing wherein the testing occurs before the bonding so that if the coil has not been properly wound, it can be repaired and need not be scraped.

It is a further object to this invention to provide an improved arrangement, which minimizes the cooling time and thus, permits quicker assembly and lower assembly and testing costs.

### SUMMARY OF INVENTION

A first feature of the invention is adapted to be embodied in a method of winding, heat-bonding and testing an electrical coil. The method comprises the winding of the electrical coil around a pole tooth of a core using a winding machine. After the wound electrical coil is formed, it is connected to a testing device for testing the winding. The connection of the wound electric coil to the testing device is then switched to an energization-heating device for energization heating to bond the coil by fusion of a resin applied to the coil. Thereafter, the lead wires are assembled to the wound and bonded electrical coil.

Another feature of the invention is adapted to be embodied in an apparatus for winding, heat-bonding and testing an electrical coil. The apparatus comprises a winding machine for winding the electrical coil and a combined testing device for testing the winding and energization-heating device for energization heating the winding to bond the electrical coil by fusion of a resin applied to the coil in a single station. A switching mechanism switches the connection of the wound electrical coil from the testing device to the energization-heating device.

### BRIEF DESCRIPTION OF DRAWINGS

FIG. 1 is a cross sectional view taken through a magneto generator which may be formed from either the prior art method or the method embodying the invention to show the construction of the components.

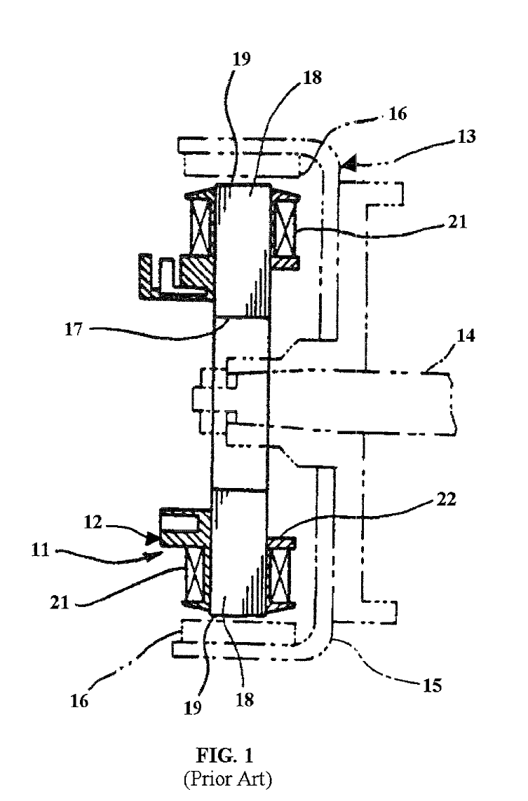

FIG. 2 is a block diagram showing the conventional method of winding the coils, energization heating them, assembling them and testing them.

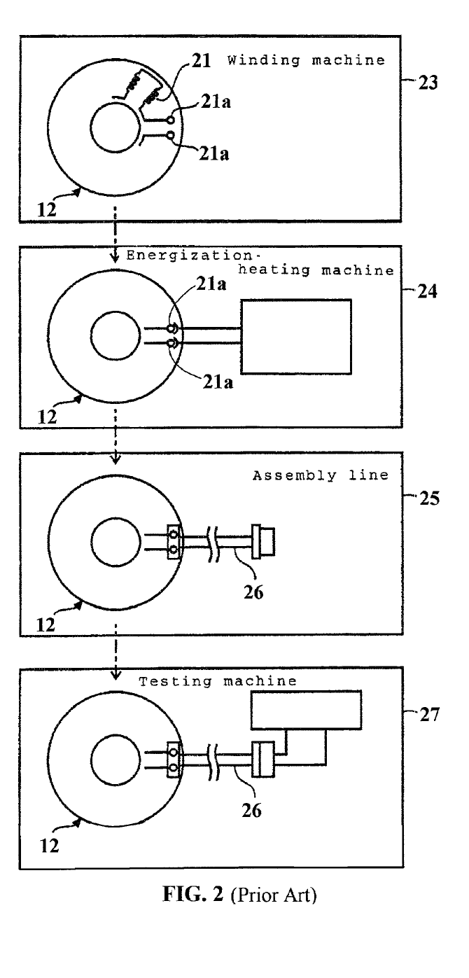

FIG. 3 is a block diagram showing, on the left side, the steps of the prior art method and, on the right hand side, the steps in the method embodying the invention.

FIG. 4 is a partially schematic view, in part similar to FIG. 2, but shows the apparatus in accordance with the invention.

FIG. 5 is a more detailed view showing the combined testing and bonding apparatus of the invention.

FIG. 6 is timing diagram showing the timing chart in accordance with the method by which the apparatus in FIG. 5 works.

### DETAILED DESCRIPTION

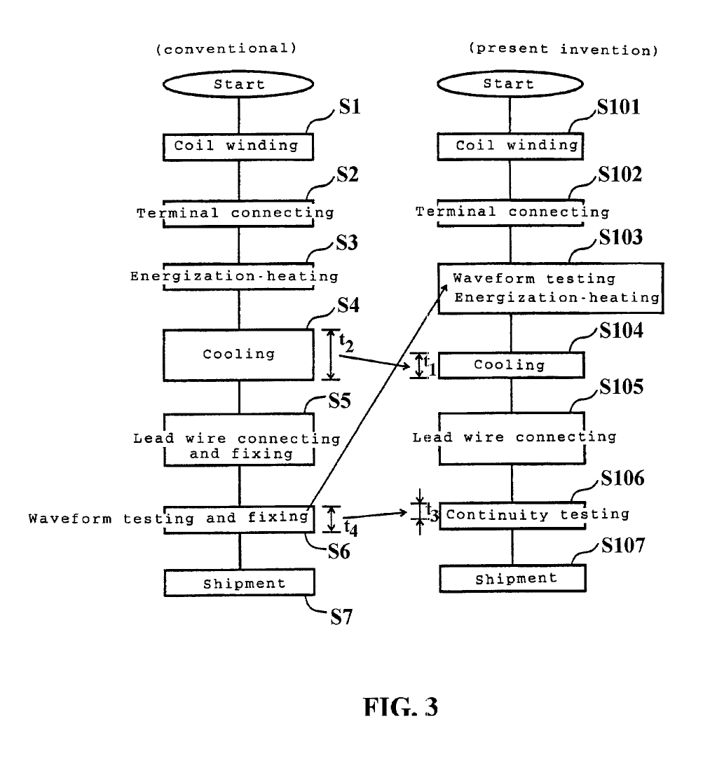

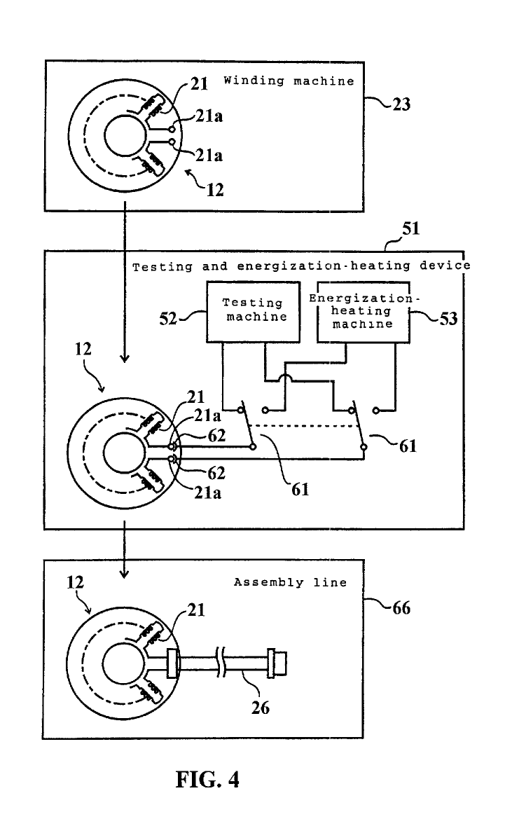

Referring now primarily to the right hand side of FIG. 3 and to FIG. 4, the apparatus and method for performing the invention will be described in detail. The apparatus is shown in FIG. 4, and the method, 1s shown at the right hand side of FIG. 3. The initial step and apparatus of the invention is the same as the prior art. It begins at the step S101 where the coil core 17 is placed into a conventional type of winding machine 23 so that the coils 21 may be wound and the terminals 21 a attached.

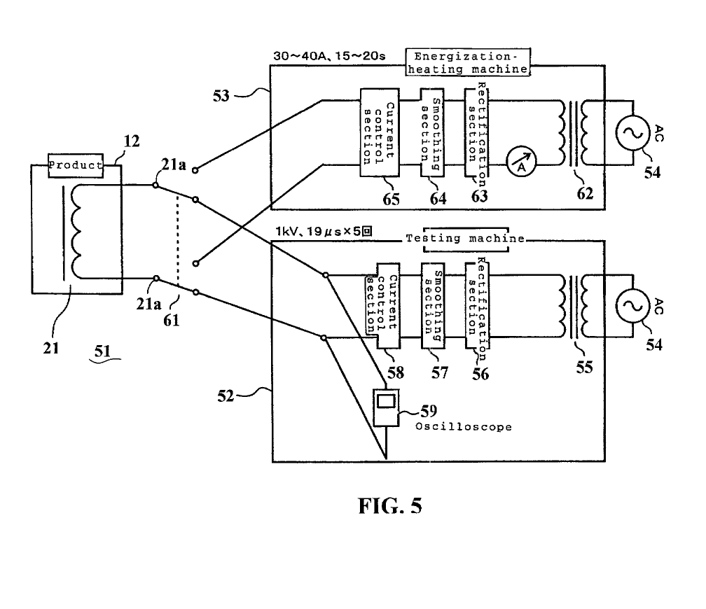

This attachment step is indicated at the step S102 and is basically the same as the step S2 of the prior art method. However, the wound stator 12 is then removed from the winding machine 23 and placed into a machine, indicated generally by the reference numeral 51, which has a combined testing device and energization heating device. This machine 51 has, as shown also in FIG. 5, a testing machine portion 52 and an energization heating machine portion 53.

The testing machine portion 52 has a connection to an AC power source 54 with a power transformer 55 that steps up the voltage from the AC source 54 and then delivers it to a rectifying section 56. The output of the rectifying section 56 is passed through a smoothing section 57 to a current control section 58. An oscilloscope 59 is connected across the outputs of the current control section and is connected to a two pole, two-way switch 61. This switch 61 selectively couples the terminal ends 21 a that are connected to terminals 62 of the machine 51 to either the testing machine portion 52 or the heat energizing portion 53.

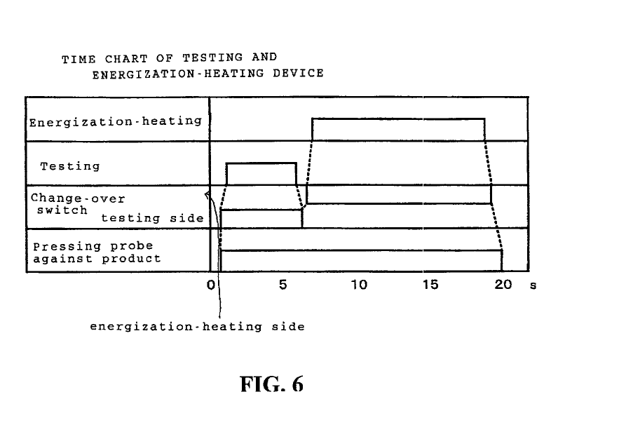

Unlike the prior art, before the energization heating the testing of the winding 21 is accomplished. This is done for example by applying a pulse of 1 K volts for 19 μ second time widths to the coil winding 21 fives times at given time intervals (FIG. 6).

Changes in voltage and current on the winding 21 are determined by the oscilloscope 59. This testing is done at the first phase of the step S1103.

Assuming the winding is properly made, and then the switch 61 is switched over to connect to the energization-heating machine portion 53. As seen in FIG. 3, this also includes a suitable electric power source, which may be the same source 54 and a step up transformer 62 that steps up the voltage which is, in turn, delivered to a rectifying section 63. The output of the rectifying section 63 is delivered to a smoothing section 64. The output from the smoothing section 64 is applied to a current control section 65 so as to energize the coil winding 21 with a large current such as 30 or 40 amps for a given time period, such as 15 to 20 seconds, so as to heat the winding of the stator 12 and achieve the bonding of the resinous material (FIG. 6).

Thus, these operations all take place at the step S,103. As has been previously noted, this is done in such a way that if the winding 21 is not satisfactory, the stator 12 can be removed from the testing and heating machine 51 and repaired.

After this combined testing and heating is successfully completed, the program moves to the step S104 so as to provide a cooling time period. Also since the energization heating takes place after the testing, the cooling time period can be significantly shortened as shown in FIG. 3 by the time ranges t1 and t2.

This is because the only step following is the lead wire connection which is done at the step S105 and is the same as that in the conventional step S5. Then there is merely made a continuity test at the step S106 which again takes place over a shorter time period T3 than the longer time period T4 applied with the conventional waveform testing of the prior art step.

Then, the device can be shipped at the step S107 and this is done with a much simpler structure and in a shorter time period so as to reduce costs. Also, as noted, the testing is done at a time when it would still be possible to repair the device and not scrap it.

Thus, from the foregoing description it should be readily apparent that the described embodiment of the invention provides a very rapid and low cost yet highly efficient way for completing the construction and testing of a coil winding. Of course, the foregoing description is that of a preferred embodiment of the invention, and various changes and modifications may be made without departing from the spirit and scope of the invention, as defined by the appended claims.

1. A method of winding, heat bonding and testing an electrical coil and energization-heating the same after winding the electrical coil around a pole tooth of a core using a winding machine, said method comprising the steps of winding the electrical coil, connecting the wound electrical coil to a testing device and testing the winding, switching the connection of the wound electrical coil between the testing device and an energization-heating device for energization-heating to bond the coil by fusing a resin applied to the coil and thereafter assembling lead wires to the wound and bonded electrical coil.

2. The method as set forth in claim 1 wherein the steps of connecting the wound electrical coil to a testing device and testing the winding, switching the connection of the wound electrical coil between a testing device and an energization-heating device are all conducted in the same apparatus.

3. The method as set forth in claim 2 wherein the steps of connecting the wound electrical coil to a testing device and testing the winding, switching the connection of the wound electrical coil between the testing device and an energization-heating device are conducted without moving the electric coil.

4. The method as set forth in claim 3 wherein the testing is performed before the energization-heating.

5. The method as set forth in claim 1 wherein a plurality of electric coils are wound on core teeth of a single coil assembly.

6. The method as set forth in claim 5 wherein the steps of connecting the wound electrical coils to a testing device and testing the windings, switching the connection of the wound electrical coils between a testing device and an energization-heating device are all conducted in the same apparatus.

7. The method as set forth in claim 6 wherein the steps of connecting the wound electrical coils to a testing device and testing the windings, switching the connection of the wound electrical coils between the testing device and an energization-heating device are conducted without moving the electric coils.

8. The method as set forth in claim 7 wherein the testing is performed before the energization-heating.

9. The method as set forth in claim 8 wherein the energization-heating is not performed unless the testing produces satisfactory results.

10. An apparatus for winding, heat bonding and testing an electrical coil comprising a winding machine for winding said electrical coil and a combined testing device for testing the winding and energization-heating device for energization-heating the winding to bond said electrical coil by fusing a resin applied to said coil in a single station, and a switching control for switching the connection of the wound electrical coil from said testing device to said energization-heating device.
